(19) United States
(12) Patent Application Publication
(10) Pub. No.: US 2007/0111377 A1
(43) Pub. Date: May 17, 2007

(54) Connector and method for making the same

(76) Inventors: Ying Chung Chen, Pan Chiao City (TW); Chung-Nan Pao, Taipei Hsien (TW)

Correspondence Address: LIN & ASSOCIATES INTELLECTUAL PROPERTY, P.O. BOX 2339, SARATOGA, CA, 95070-0339, US

(21) Appl. No.: 11/280,369

(22) Filed: Nov. 16, 2005

(51) Int. Cl. H01L 21/00

(52) U.S. Cl. 438/106

(57) ABSTRACT

A connector includes a terminal which includes a base with an arm extending inclinedly therefrom and a first contact portion protrudes from a top of a front end of the arm, The front end extends inclinedly from the first contact portion and has a sharp tip. A plastic frame has insertion slots for receiving the terminals and a wire space defined in a top of the plastic frame so as to receive wires therein and a plurality of receiving spaces are defined in the plastic frame and communicate with the insertion slots. A plurality of access slots are defined in the top of the plastic frame and the first contact portions of the terminals extend from the access slots so as to contact the wires. A cavity is defined in a front of each of the receiving spaces so as to receive the front end of the terminal.

### BACKGROUND OF THE INVENTION

1. Field of the Invention

The present invention relates to a connector which has better structural strength to prevent from being deformed and a method for making the terminal, the plastic frame and the metal case of the connector.

2. The Prior Arts

A conventional connector 10 is shown in FIGS. 1A to 1D and generally includes a terminal 12, an earth leg 14, a plastic frame 16 and a metal case 18. As shown in FIG. 1B, the terminal 12 includes an arm 12a and a contact portion 12b protruding from a top of the front end thereof. When the terminal 12, the earth leg 14, the plastic frame 16 and the metal case 18 are assembled to be the connector 10, if the wires (not shown) are to be installed to the grooves 15 on the front side of the plastic frame 16, a force 11 as indicated in FIG. 1B is applied to the contact portion 12b and the force 11 makes the contact portion 12b to raise upward.

Besides, when bending the terminal 12, in order to make a bent terminal rear end 12c and the contact portion 12b, the arm 12a includes a section that is wider than the terminal rear end 12c and contact portion 12b. In order to let the terminal 12 successfully insert into the insertion slots 16a, 16b of the plastic frame 16, as shown in FIG. 1A and FIG. 1C, the separation portion between the insertion slots 16a, 16b become thinner and the thinner separation portions make the plastic frame 16 to be less stronger. Furthermore, as shown in FIG. 1D, the earth leg 14 includes a plurality of plates 14a so that the plastic frame 16 has to have a plurality of earth slots 16c, 16d as shown in FIG. 1C, the earth slots 16c, 16d weaken the structural strength of the plastic frame 16.

### SUMMARY OF THE INVENTION

A primary objective of the present invention is to provide a connector and a method for making the terminal, the plastic frame and the metal case of the connector, wherein the plastic frame includes a cavity for engaging the front end of the terminal so as to prevent the front end of the terminal from being raised upward.

A second objective of the present invention is to provide a connector and a method for making the terminal, the plastic frame and the metal case of the connector, wherein the terminal is made slim and only earth leg is required so that the plastic frame can be made stronger than the conventional plastic frames.

A third objective of the present invention is to provide a connector and a method for making the terminal, the plastic frame and the metal case of the connector, wherein the metal case includes two earth plates which are in contact with the plastic frame and the single earth leg, so that there will be not necessary to make multiple holes in the rear end of the plastic frame.

According to the present invention, a connector includes a terminal and a plastic frame, wherein the terminal includes a base with an arm extending inclinedly therefrom and a first contact portion protrudes from a top of a front end of the arm, The front end extends inclinedly from the first contact portion and has a sharp tip. The plastic frame has insertion slots for receiving the terminals and a wire space defined in a top of the plastic frame so as to receive wires therein and a plurality of receiving spaces are defined in the plastic frame and communicate with the insertion slots. A plurality of access slots are defined in the top of the plastic frame and communicate with the receiving spaces and wire space. The first contact portions of the terminals extend from the access slots and a cavity is defined in a front of each of the receiving spaces so as to receive the front end of the terminal.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A to 1D show a conventional connector, and

FIGS. 2A to 2H show the connector of the present invention.

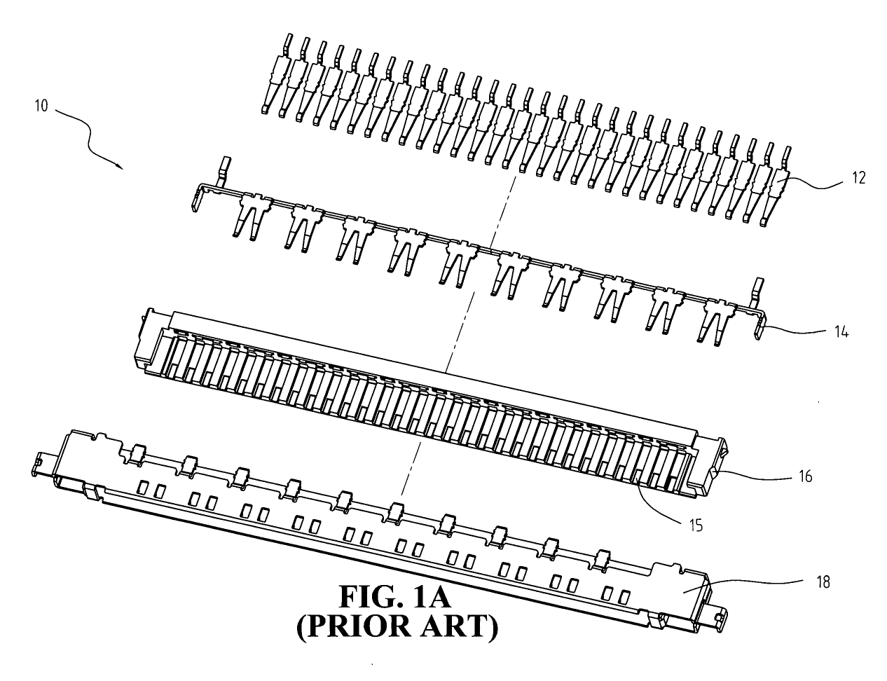

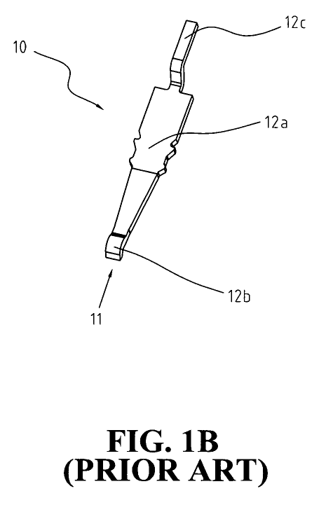

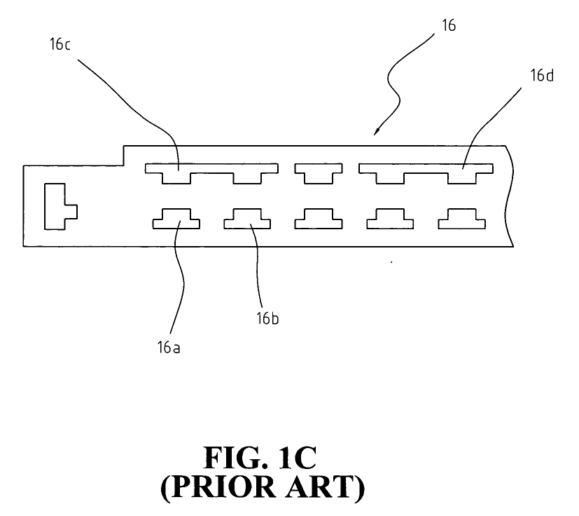

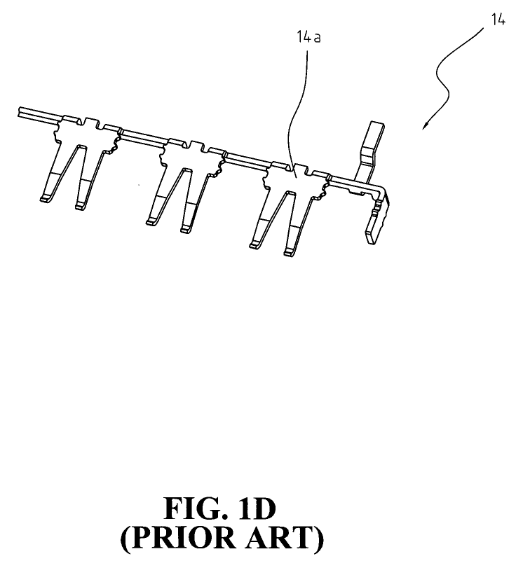

### DETAILED DESCRIPTION OF THE PREFERRED EMBODIMENT

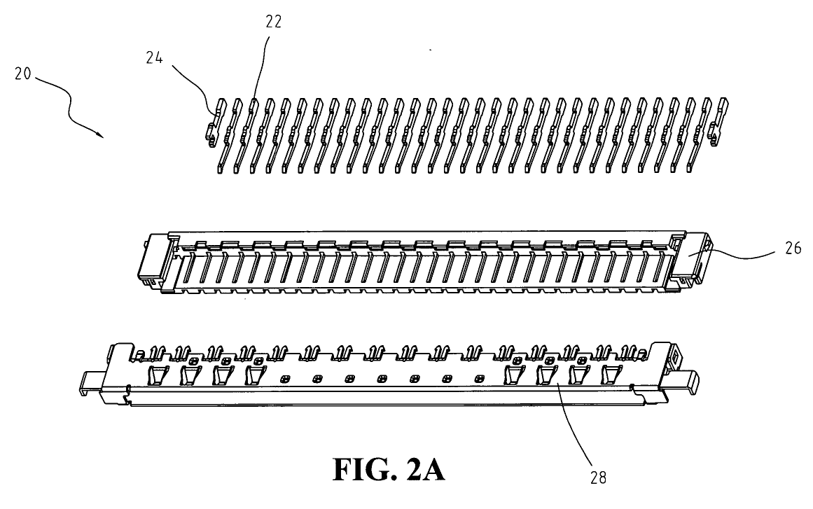

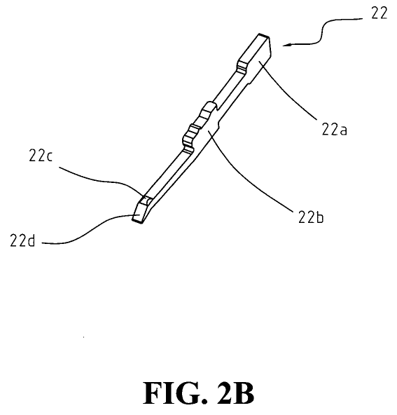

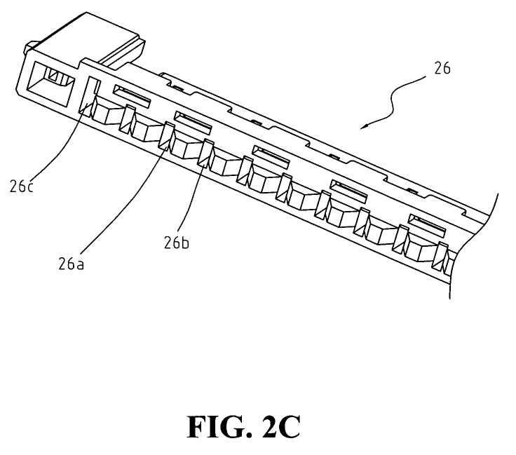

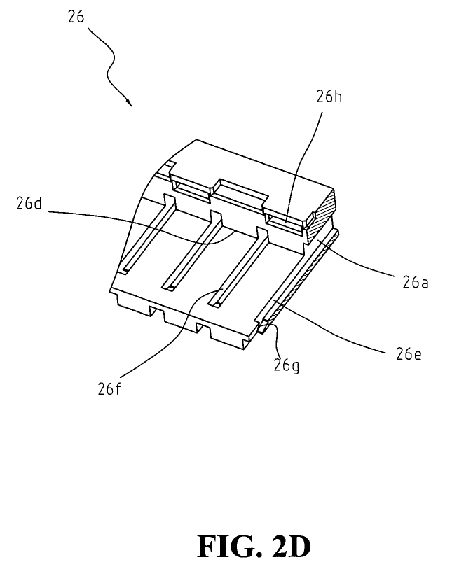

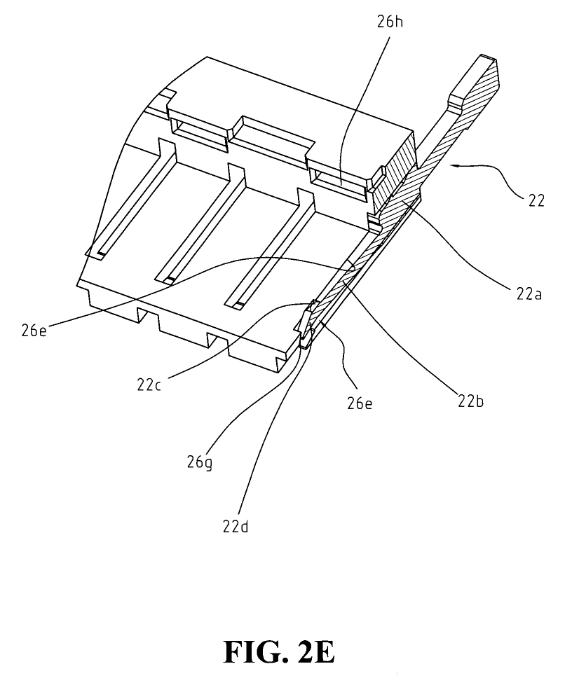

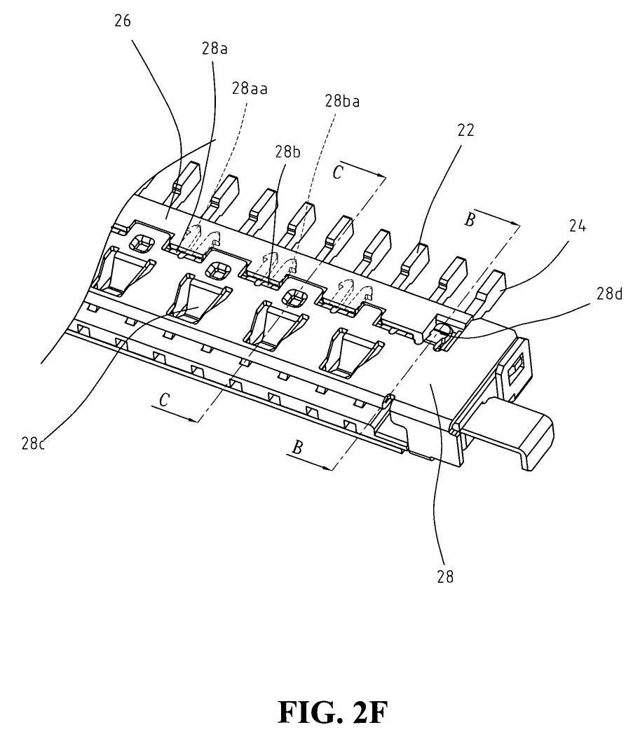

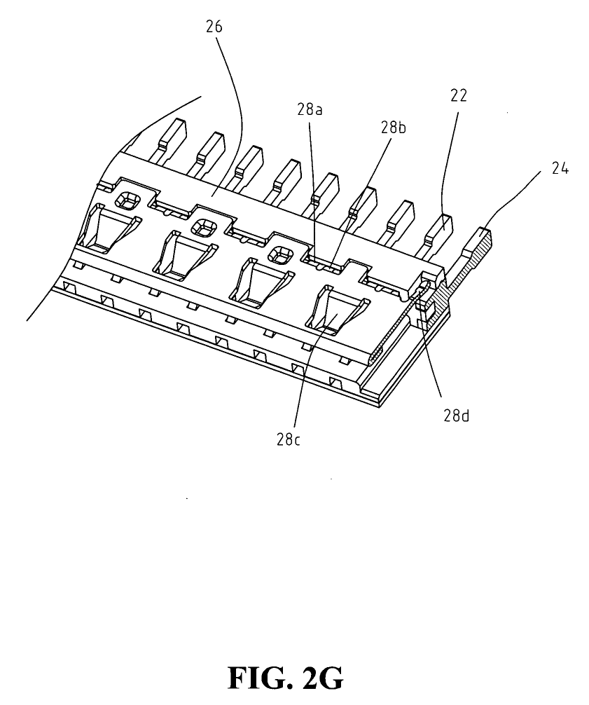

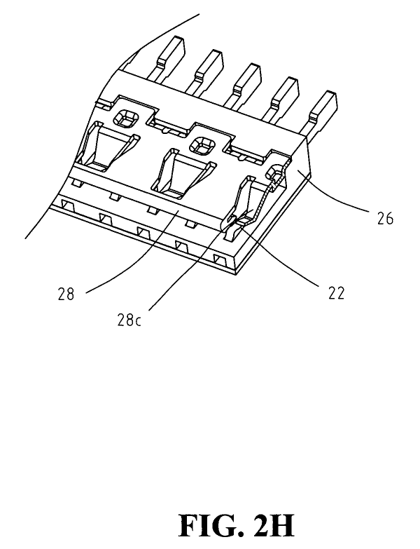

With reference to the drawings and in particular to FIGS. 2A to 2E, a connector of the present invention comprises a terminal 22 and a plastic frame 26. As disclosed in FIG. 2A, the terminal 22 and the plastic frame 26 can achieve the purpose of the primary object of the present invention. If the terminal 22 is made to be slim and cooperates with a single earth leg 24 can achieve the purpose of the second object of the present invention. When cooperated with a metal case 28 and the earth leg 24, the purpose of the third object of the present invention can be achieved.

The terminal 22 has a base 22a, an arm 22b extending inclinedly from the base 22a, and a first contact portion 22c protruding from a top of a front end 22d of the arm 22b. The front end 22d extends inclinedly from the first contact portion 22c and has a sharp tip. The plastic frame 26 has insertion slots 26a, 26b defined in a rear end thereof so that the terminals 22 extends into the insertion slots 26a, 26b so that the terminals 22 are inserted into the insertion slots 26a, 26b. A wire space 26d is defined in a top of the plastic frame 26 so that wires (not shown) can be received therein. A plurality of receiving spaces 26e are defined in the plastic frame 26 and communicate with the insertion slots 26a, 26b and a plurality of access slots 26f are defined in the top of the plastic frame 26 and communicate with the receiving spaces 26e and wire space 26d. The first contact portions 22c of the terminals 22 extend from the access slots 26f and are in contact with the wires. The access slot 26f are elongate slots and slightly wider than the terminals 22 so that the terminals 22 are well positioned in the access slot 26f. The terminals 22 can be made to be slim so that the sizes of the insertion slots 26a, 26b can be made smaller. By this way, the separation portions between the insertion slots 26a, 26b can be made wider which means the plastic frame 26 have better structural strength. A cavity 26g is defined in a front of each of the receiving spaces 26e so as to receive the front end 22d of the terminal 22 when the terminals 22 are inserted into the insertion slots 26a, 26b. Because the arm 22b extends inclinedly and upward so that the receiving space 26e is not completely filled by the terminal 22, therefore, the first contact portion 22c and the front end 22d can be further compressed downward. When the wires are put in the wire space 26d, the wires push the first contact portions 22c downward and the arm 22b is applied a reaction force to the wire by its nature so that the wires can be well positioned in the wire space 26d of the plastic frame 26. Besides, during the installation of the wires, the front end 22d is engaged with the cavity 26g so that the front end 22d of the terminal 22 will not bend upward.

As shown in FIG. 2C, the plastic frame 26 includes an earth slot 26c which communicates with an aperture on a top of the plastic frame 26. An earth leg 24 is shaped to fit in the earth slot 26c. The present invention has only one earth leg 24 which is not composed of multiple plates as disclosed in the conventional earth leg so that only one earth slot 26c is needed and the only one earth slot 26c does not weaken the structural strength of the plastic frame 26. When cooperated with a metal case 28, the present invention can still have desired earth feature.

As disclosed in FIGS. 2F, 2G and 2H, the metal case 28 is a hollow case and covers the wire space 26 and has a pair of engaging members extending from a front end thereof. Two engaging portions 28a, 28b extend from the metal case 28 to form the engaging members. The two engaging portions 28a, 28b each have a hook end 28aa/28ba. The plastic frame 26 includes an engaging hole 26h which includes a narrow opening so as to defined two shoulders in the engaging hole 26h so that the two hook ends 28aa, 28ba are engaged with the two shoulders in the engaging hole 26h. A first earth plate 28c is located between the two engaging members and extends into the metal case 28. The first earth plate 28c has a second earth plate 28d which is in contact with wires. The second earth plate 28d is located on a rear end of the metal case 28 and the earth leg 24 protrudes from an earth opening so that the second earth plate 28d is in contact with the earth leg 24. Therefore, the first earth plate 28c is in contact with the wires and the second earth plate 28d is in contact with the earth leg 24, so that the connector can be earth by the nature of the metal material of the metal case 28.

The terminal 22, the plastic frame 26, the metal case 28 are made by using three respective mold sets.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method for making a terminal, comprising the following steps:
a step of providing a mold set which makes a terminal with a base, an arm extending inclinedly from the base, a first contact portion protruding from a top of a front end of the arm, the front end extending inclinedly from the first contact portion and having a sharp tip, and
a step of making the terminal by the mold set.

2. A method form making a plastic frame, comprising the following step:
a step of providing a mold set which makes a plastic frame having insertion slots, a wire space, a plurality of receiving spaces, a plurality of access slot and a cavity, the insertion slots defined in a rear end of the plastic frame and a wire space defined in a top of the plastic frame, each of the insertion slots communicating with respective one of two receiving spaces which are adapted to receive two respective arms of terminals, the access slots communicating with the receiving spaces and wire space, each of the access slots being sized to be adapted to a receive first contact portion of the terminal, the cavity defined in a front of each of the receiving spaces so as to be adapted to receive a front end of the terminal, and
a step of making the plastic frame by the mold set.

3. The method as claimed in claim 2, wherein the plastic frame includes an engaging hole which includes a narrow opening so as to defined two shoulders in the engaging hole.

4. The method as claimed in claim 2, wherein the plastic frame includes an earth slot which communicates with an aperture on a top of the plastic frame.

5. A method for making a metal case, comprising the following steps:
a step of providing a mold set which makes a metal case having a pair of engaging members, a first earth plate and a second earth plate, the metal case being a hollow case and having two engaging portions extending therefrom which form the engaging members, the two engaging portions each having a hook end, the first earth plate located between the two engaging members and extending into the metal case, the second earth plate adapted to be in contact with an earth leg via an earth opening, and
a step of making the metal case by the mold set.

6. A connector comprising:
a terminal having a base, an arm extending inclinedly from the base, a first contact portion protruding from a top of a front end of the arm, the front end extending inclinedly from the first contact portion and having a sharp tip, and
a plastic frame having insertion slots defined in a rear end thereof so that the terminals extends into the insertion slots, a wire space defined in a top of the plastic frame for being adapted to receive wires, a plurality of receiving spaces defined in the plastic frame and communicating with the insertion slots, a plurality of access slots defined in the top of the plastic frame so as to communicate with the receiving spaces and wire space, the first contact portions of the terminals extending from the access slots, the access slot being elongate slots and a cavity defined in a front of each of the receiving spaces so as to receive the front end of the terminal.

7. The connector as claimed in claim 6, wherein the plastic frame includes an engaging hole which includes a narrow opening so as to defined two shoulders in the engaging hole, a metal case being a hollow case and covering the wire space and having a pair of engaging members extending from a front end thereof, two engaging portions extending from the metal case so as to form the engaging members, the two engaging portions each having a hook end.

8. The connector as claimed in claim 7, wherein a first earth plate is located between the two engaging members and extends into the metal case, the first earth plate has a second earth plate which are adapted to be in contact with wires.

9. The connector as claimed in claim 7, wherein the plastic frame includes an earth slot which communicates with an aperture on a top of the plastic frame, an earth leg which is shaped to fit in the earth slot.

10. The connector as claimed in claim 9, wherein the metal case has a second earth plate on a rear end thereof and the earth leg protrudes from an earth opening so that the second earth plate is in contact with the earth leg.
